(19) United States
(12) Patent Application Publication
(10) Pub. No.: US 2025/0089372 A1
(43) Pub. Date: Mar. 13, 2025

(54) Display Device

(71) Applicant: LG Display Co., Ltd., Seoul (KR)

(72) Inventors: Daeyoung Seo, Seoul (KR); Hun Jang, Paju-si, Gyeonggi-do (KR); ByungHyun Lee, Paju-si, Gyeonggi-do (KR); MinSeok Kim, Seoul (KR); TaeYong Kim, Anyang-si, Gyeonggi-do (KR); Juhyun Nam, Seoul (KR); Sumin Lee, Seoul (KR)

(21) Appl. No.: 18/670,578

(22) Filed: May 21, 2024

(30) Foreign Application Priority Data
Sep. 13, 2023 (KR) 10-2023-0121471

(51) Int. Cl. H01L 27/12; H01L 25/075; H01L 25/16; H01L 33/62

(52) U.S. Cl. CPC H10D 86/60; H01L 25/0753; H01L 25/167; H10D 86/443; H10D 86/481; H10H 20/857

(57) ABSTRACT

A display device comprises a substrate including a plurality of pixel areas that are spaced apart from each other and a plurality of transmissive areas between the plurality of pixel areas, wherein each of the plurality of pixel areas includes a plurality of sub pixels; and a plurality of signal lines that extend in a first direction on the substrate, wherein the plurality of sub pixels include a plurality of pixel circuits, wherein the plurality of signal lines overlap the plurality of pixel circuits without the plurality of signal lines overlapping the plurality of transmissive areas. Accordingly, the plurality of pixel areas and the plurality of signal lines are in the same area to reduce the size of the opaque area in the entire display device and enlarge a size of the transmissive area to implement a transparent display device.

### CROSS-REFERENCE TO RELATED APPLICATION

This application claims the priority of Republic of Korea Patent Application No. 10-2023-0121471 filed on Sep. 13, 2023, in the Korean Intellectual Property Office.

### BACKGROUND

### Field

The present disclosure relates to a transparent display device, and more particularly, to a transparent display device using a light emitting diode (LED).

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance may be displayed.

### SUMMARY

An object to be achieved by the present disclosure is to provide a transparent display device with a high transmittance.

Another object to be achieved by the present disclosure is to provide a display device in which a size of a transmissive area is maximized.

Another object to be achieved by the present disclosure is to provide a display device in which interference between a driving transistor of the pixel area and a plurality of data lines is reduced.

Another object to be achieved by the present disclosure is to provide a display device which reduces fluctuation of a voltage and a driving current of a driving transistor due to a data line.

Still another object to be achieved by the present disclosure is to provide a display device which reduces coupling between a data line and a driving transistor to improve a display quality.

Objects of the present disclosure are not limited to the above-mentioned objects, and other objects, which are not mentioned above, can be clearly understood by those skilled in the art from the following descriptions.

The present disclosure provides display devices according to the independent claims. Preferred embodiments are described in the dependent claims. According to one embodiment of the present disclosure, a display device comprises: a substrate including a plurality of pixel areas that are spaced apart from each other and a plurality of transmissive areas between the plurality of pixel areas; and a plurality of data lines that extend in a first direction on the substrate, wherein the plurality of pixel areas overlap the plurality of data lines without the plurality of data lines overlapping the plurality of transmissive areas. The first direction described herein may be a column direction. A second direction described herein may be a row direction.

In one embodiment, a display device comprises: a substrate including a pixel area and a light transmitting area that is more transparent than the pixel area; a first insulating layer on the substrate; a driving transistor on the first insulating layer in the pixel area; a signal line overlapping the driving transistor in the pixel area; a light emitting element in the pixel area, the light emitting element electrically connected to the driving transistor, and a second insulating layer between the signal line and the driving transistor in the pixel area, the second insulating layer having a thickness that is greater than a thickness of the first insulating layer.

In one embodiment, a display device comprises: a substrate in which a plurality of pixel areas disposed to be spaced apart from each other and a plurality of transmissive areas disposed between the plurality of pixel areas are defined; and a plurality of wiring lines extending in a column direction on the substrate, wherein the plurality of pixel areas overlap an area in which the plurality of wiring lines are disposed.

Other detailed matters of the exemplary embodiments are included in the detailed description and the drawings.

According to an aspect of the present disclosure, a transparent display device with an improved transmittance may be implemented.

According to another aspect of the present disclosure, opaque configurations, among configurations of the display device overlap each other to maximize a size of a transmissive area in the display device. According to some embodiments, an opaque pixel area and a plurality of wiring lines overlap to maximize the size of the transmissive area.

According to another aspect of the present disclosure, the voltage fluctuation of the driving transistor due to the coupling of the data line and the driving transistor and a fluctuation of a driving current thereby may be reduced.

According to another aspect of the present disclosure, a cross talk and a luminance change due to the coupling of the data line and the driving transistor may be reduced.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a schematic enlarged plan view of an active area of a display device according to an exemplary embodiment of the present disclosure;

FIG. 4 is an enlarged plan view of an active area of a display device according to an exemplary embodiment of the present disclosure;

FIG. 5 is a cross-sectional view of a sub pixel of a display device according to an exemplary embodiment of the present disclosure;

FIG. 6 is a simulation result of measuring a cross talk level according to a thickness of an insulating layer;

FIG. 7 is an enlarged plan view of a display device according to another exemplary embodiment of the present disclosure;

FIG. 8 is a cross-sectional view of a sub pixel of a display device according to another exemplary embodiment of the present disclosure;

FIG. 9A is a graph obtained by measuring a voltage and a driving current of a driving gate electrode according to a data voltage in a display device according to a comparative embodiment; and

FIG. 9B is a graph obtained by measuring a voltage and a driving current of a driving gate electrode according to a data voltage in a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but may be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be disposed directly on the other element or layer, or yet another layer or element may be disposed between the element or layer and the other element or layer.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to the accompanying drawings.

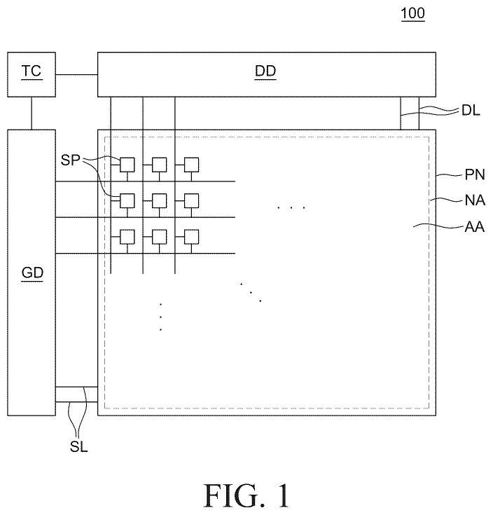

FIG. 1 is a schematic diagram of a display device 100 according to an exemplary embodiment of the present disclosure. In FIG. 1, for the convenience of description, among various components of the display device 100, a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD supplies a data voltage to a plurality of data lines DL (e.g., signal lines) according to a plurality of data control signals and image data supplied from the timing controller TC. The data driver DD converts the image data into a data voltage using a reference gamma voltage and may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP are connected to the scan lines SL and data lines DL at the intersections of the scan lines SL and the data lines DL.

In the display panel PN, an active area AA and a non-active area NA may be defined.

The active area AA is an area in which images are displayed in the display device 100. In the active area AA, a plurality of sub pixels SP which configure a plurality of pixels PX and a pixel circuit (or a plurality of pixel circuits) for driving the plurality of sub pixels SP may be disposed. The plurality of sub pixels SP is a minimum unit which configures the active area AA and n sub pixels SP form one pixel PX (e.g., n=3 or n=4). In each of the plurality of sub pixels SP, a light emitting diode 120 and a thin film transistor for driving the light emitting diode 120 may be disposed. The plurality of light emitting diodes 120 of the plurality of sub pixels SP may be defined in different ways depending on the type of the display panel PN. For example, when the display panel PN is an inorganic light emitting display panel, each of the light emitting diodes 120 may be a light emitting diode (LED) or a micro light emitting diode (LED).

In the active area AA, a plurality of signal lines which transmit various signals to the plurality of sub pixels SP are disposed. For example, the plurality of signal lines include a plurality of data lines DL which supply a data voltage to each of the plurality of sub pixels SP and a plurality of scan lines SL which supply a scan signal to each of the plurality of sub pixels SP. The plurality of scan lines SL extend in one direction in the active area AA to be connected to the plurality of sub pixels SP and the plurality of data lines DL extend in a direction different from the one direction in the active area AA to be connected to the plurality of sub pixels SP. In addition, in the active area AA, a low potential power line and a high potential power line may be further disposed, but the present disclosure is not limited thereto.

The non-active area NA is an area where images are not displayed so that the non-active area NA may be defined as an area extending from the active area AA. In one embodiment, the non-active area NA surrounds the active area AA in the plan view of the display device. In the non-active area NA, a link line which transmits a signal to a sub pixel SP of the active area AA, a pad electrode, or a driving IC, such as a gate driver IC or a data driver IC, may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board and the display panel PN is electrically connected to the data driver DD and the timing controller TC by bonding the flexible film and the printed circuit board to the pad electrode formed in the non-active area NA of the display panel PN.

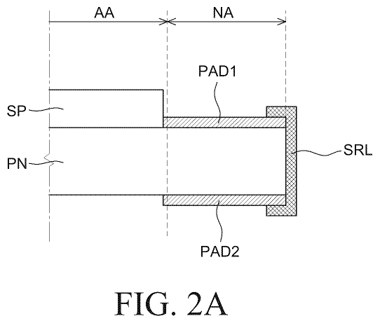

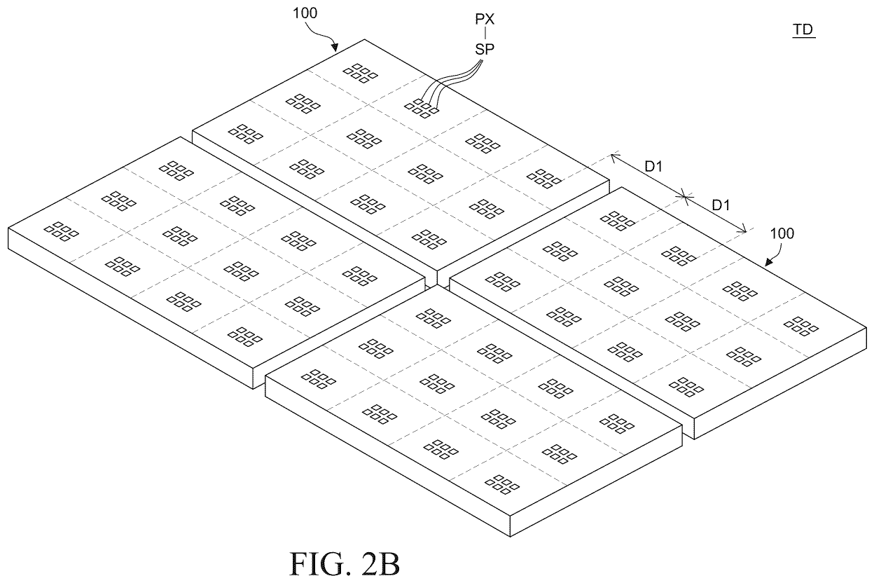

As another example, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. Therefore, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP are disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extend from the active area AA to the non-active area NA to be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a driving component is disposed on a rear surface of the display panel PN and a signal transmission path between the front surface and the rear surface of the display panel PN is formed to minimize a size of the non-active area NA on the front surface of the display panel PN.

Further, referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, one pixel PX may include a plurality of sub pixels SP and a distance D1 between an outermost pixel PX of one display device 100 and an outermost pixel PX of another display device 100 adjacent to the one display device may be implemented to be equal to a distance D1 between pixels PX in the one display device 100. Accordingly, the distance between pixels PX between the display devices 100 is configured to be constant so as to minimize the seam area.

However, FIGS. 2A and 2B are illustrative so that the display device 100 according to the exemplary embodiment of the present disclosure may be a general display device with a bezel, but is not limited thereto.

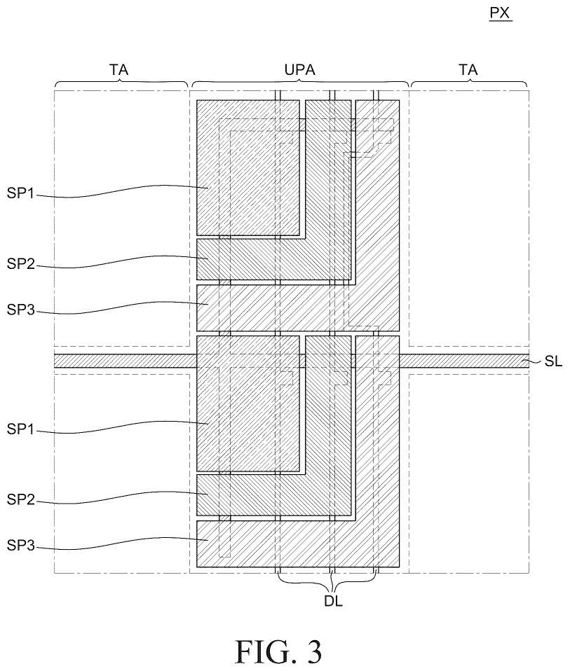

Hereinafter, a display panel PN of a display device 100 according to an exemplary embodiment of the present disclosure will be described in more detail with reference to FIGS. 3 to 6.

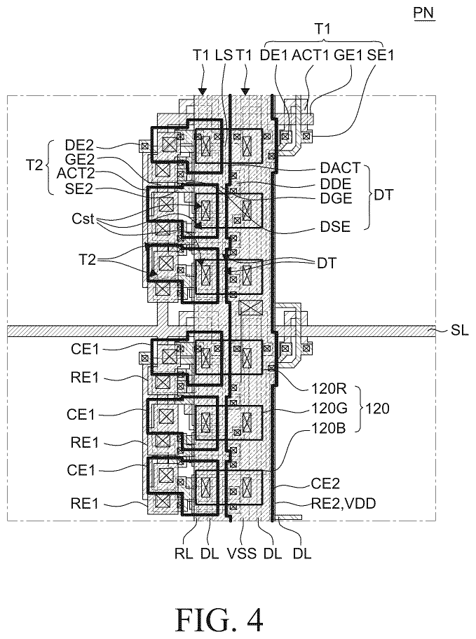

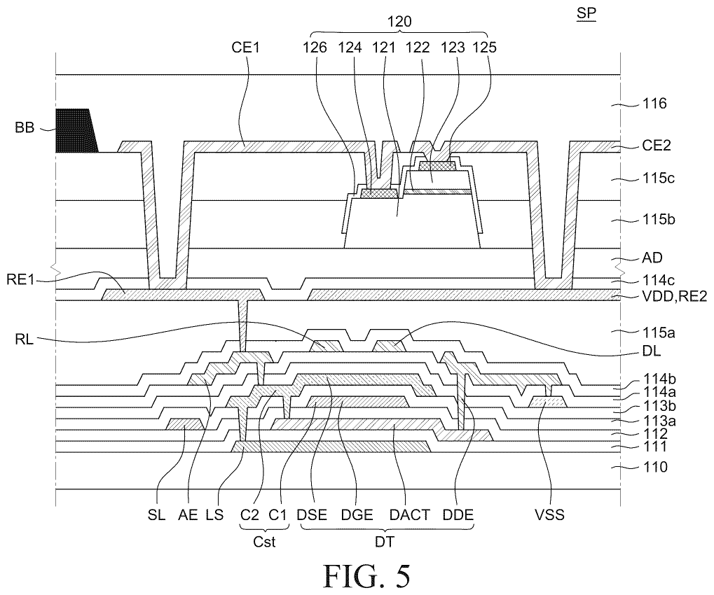

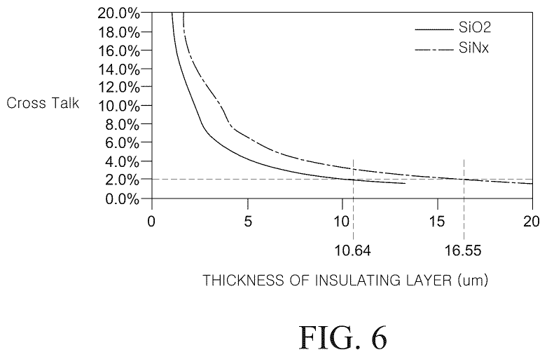

FIG. 3 is a schematic enlarged plan view of a pixel unit of an active area of a display device according to an exemplary embodiment of the present disclosure. FIG. 4 is an enlarged plan view of an active area of a display device according to an exemplary embodiment of the present disclosure. FIG. 5 is a cross-sectional view of a sub pixel of a display device according to an exemplary embodiment of the present disclosure. FIG. 6 is a simulation result of measuring a cross talk level according to a thickness of an insulating layer. In FIG. 3, for the convenience of description, among a plurality of wiring lines, only scan lines SL and data lines DL are illustrated and only one pixel area UPA, among a plurality of pixel areas UPA, and a plurality of transmissive areas TA which enclose the one pixel area UPA are illustrated.

Referring to FIG. 3, in the active area AA, a pixel area UPA in which pixels PX are formed and a plurality of transmissive areas TA which enclose the pixel area UPA are formed. In one embodiment, each transmissive area TA lacks pixels PX and is more transparent than the pixel area UPA. In each pixel PX of the active area AA, a pixel circuit including a driving element and a light emitting diode 120 which is driven by the pixel circuit are formed so that the plurality of pixel areas UPA in which pixels PX are formed may be substantially opaque areas. Further, the plurality of transmissive areas TA in which the pixels PX are not formed may be substantially transparent areas. In this case, the pixel area UPA which is defined by a pixel PX being formed therein is an area in which light emitted from the light emitting diode 120 is displayed so that it is also defined as an emission area. Further, the pixel area UPA which is defined by the pixel PX being formed therein is an area in which a pixel circuit including a driving element is formed so that it may also be defined as a circuit area.

In the active area AA, a plurality of pixel areas UPA is formed. Each of the plurality of pixel areas UPA is an area in which a driving element and a light emitting diode 120 are disposed to display images. The plurality of pixel areas UPA may be disposed to be spaced apart from each other with a plurality of transmissive areas TA therebetween. For example, the plurality of pixel areas UPA may be disposed by forming a plurality of rows and a plurality of columns.

A plurality of sub pixels SP are disposed in each of the plurality of pixel areas UPA. Each of the plurality of sub pixels SP includes a light emitting diode 120 and a pixel circuit to independently emit light. For example, the plurality of sub pixels SP may include a first sub pixel SP1, a second sub pixel SP2, and a third sub pixel SP3 which emit different color light. For example, the first sub pixel SP1 is a red sub pixel, the second sub pixel SP2 is a green sub pixel, and the third sub pixel SP3 is a blue sub pixel, but the present disclosure is not limited thereto.

Hereinafter, the description will be made by assuming that one pixel PX includes two first sub pixels SP1, two second sub pixels SP2, and two third sub pixels SP3, that is, for example, two red sub pixels, two green sub pixels, and two blue sub pixels, but the configuration of the pixel PX is not limited thereto.

In the meantime, one pair of first sub pixels SP1, one pair of second sub pixels SP2, and one pair of third sub pixels SP3 may be used as main sub pixels SP and redundancy sub pixels SP, respectively. For example, one first sub pixel SP1 of one pair of first sub pixels SP1, one second sub pixel SP2 of one pair of second sub pixels SP2, and one third sub pixel SP3 of one pair of third sub pixels SP3 may be main sub pixels SP which are basically used when the display device 100 is driven. When an image is displayed, the main sub pixels SP may be used according to one embodiment. Further, the remaining first sub pixel SP1 of the one pair of first sub pixels SP1, the remaining second sub pixel SP2 of the one pair of second sub pixels SP2, and the remaining third sub pixel SP3 of the pair of third sub pixels SP3 may be redundancy sub pixels SP so that when the main sub pixel SP is defective, the redundancy sub pixel SP may be used instead of the main sub pixel.

Further, a placement order of the main sub pixels SP may be configured to be the same as the placement order of the redundancy sub pixels SP. For example, the sub pixels SP which form the main sub pixels SP are disposed in the order of the first sub pixel SP1, the second sub pixel SP2, and the third sub pixel SP3. Further, the sub pixels SP which form the redundancy sub pixels SP may also be disposed in the order of the first sub pixel SP1, the second sub pixel SP2, and the third sub pixel SP3.

However, one pair of first sub pixels SP1, one pair of second sub pixels SP2, and one pair of third sub pixels SP3 are not limited to the main sub pixels SP and the redundancy sub pixels SP, but all the sub pixels may be always used while driving the display device 100. Further, the placement order of the sub pixels SP is not limited to the placement order described above.

The pixel area UPA may overlap wiring lines extending in a column direction, among the plurality of wiring lines, for example, data lines DL and reference lines RL. The column direction may be referred to as a first direction herein. The pixel area UPA is formed in an area in which a plurality of opaque wiring lines are disposed to ensure a size of the transmissive area TA in the entire active area AA. Specifically, the pixel area UPA in which the plurality of sub pixels SP are disposed has a low transmittance and is substantially an opaque area, due to the configurations such as, the pixel circuit and the light emitting diode 120 which are disposed in the plurality of sub pixels SP. Therefore, the plurality of sub pixels SP of the pixel area UPA may be disposed to overlap an opaque wiring line extending in a column direction, for example, a data line DL, a reference line RL, a low potential power line VSS, and a high potential power line VDD. Accordingly, the plurality of sub pixels SP of the pixel area UPA are disposed so as to overlap the plurality of wiring lines to reduce a size of the opaque area in the entire active area AA and maximize the size of the transmissive area TA.

The plurality of sub pixels SP disposed in one pixel area UPA may be formed to have any one of a rectangular shape and an “L” shape in a plan view of the display device. For example, one first sub pixel SP1 (e.g., a first main sub pixel), one second sub pixel SP2 (e.g., a second main sub pixel), and one third sub pixel SP3 (e.g., a third main sub pixel) are disposed at one side (e.g., a first side) of the scan line SL and one first sub pixel SP1 (e.g., a first redundancy sub pixel), one second sub pixel SP2 (e.g., a second redundancy sub pixel), and one third sub pixel SP3 (e.g., a second redundancy sub pixel) may be disposed at the other side (e.g., a second side) of the scan line SL. In one embodiment, the first main sub pixel SP1 and the first redundancy sub pixel SP1 emit a first color of light, the second main sub pixel SP2 and the second redundancy sub pixel SP2 emit a second color of light, and the third main sub pixel SP3 and the third redundancy sub pixel SP3 emit a third color of light

At each of the one side and the other side of the scan line SL, the first sub pixel SP1 is disposed in a rectangular area and the second sub pixel SP2 is disposed in an L-shaped area which encloses two adjacent sides of four sides of the first sub pixel SP1. Further, the third sub pixel SP3 may be disposed in the “L”-shaped area which encloses an outer part of the L-shaped second sub pixel SP2. Therefore, one pixel area UPA configured by the first sub pixel SP1 with a rectangular shape and the second sub pixel SP2 and the third sub pixel SP3 with an L shape may collectively form a rectangular shape. In one embodiment, the second sub pixel SP2 is between the first sub pixel SP1 and the third sub pixel SP3 in the plan view of the display device.

Each of the plurality of transmissive areas TA is an area of the active area AA excluding an area in which the plurality of wiring lines and the plurality of pixel areas UPA are disposed. That is, each transmissive area TA may be an area of the active area AA, in which none of the plurality of wiring lines are disposed. In other words, the transmissive areas TA may be free from any wiring line, pixel circuit and light emitting diode. A light transmittance of the plurality of transmissive areas TA is higher than that of the plurality of pixel areas UPA. Light is transmitted through the transmissive area TA and a background located on the rear surface of the display device 100 is seen from the front surface of the display device 100. The plurality of transmissive areas TA may be spaced apart from each other with the plurality of wiring lines and the plurality of pixel areas UPA therebetween. The plurality of transmissive areas TA may be disposed so as to enclose the plurality of pixel areas UPA. Accordingly, the display device 100 according to the exemplary embodiment of the present disclosure may be implemented as a transparent display device 100 including a plurality of transmissive areas TA.

Referring to FIGS. 3 to 5, each of the plurality of sub pixels SP includes a pixel circuit and one or more light emitting diodes 120. The pixel circuit includes a plurality of transistors T1, T2, and DT and a storage capacitor Cst to supply a driving current to the light emitting diode 120. For example, the pixel circuit may include a first transistor T1, a second transistor T2, a driving transistor DT, and a storage capacitor Cst. Further, the plurality of sub pixels SP disposed in one pixel area UPA are connected to the scan line SL, the plurality of data lines DL, the reference line RL, the high potential power line VDD, and the low potential power line VSS to be supplied with various signals.

First, the substrate 110 is a component for supporting various components included in the display device 100 and may be formed of an insulating material. For example, the substrate 110 may be formed of glass or resin. Further, the substrate 110 may be configured to include polymer or plastics or may be formed of a material having flexibility.

A light shielding layer LS is disposed in each of the plurality of sub pixels SP on the substrate 110. The light shielding layer LS blocks light incident onto a driving active layer DACT of the driving transistor DT to be described below, from below the substrate 110. Light which is incident onto the driving active layer DACT of the driving transistor DT is blocked by the light shielding layer LS to minimize a leakage current.

A buffer layer 111 is disposed on the substrate 110 and the light shielding layer LS. The buffer layer 111 may reduce permeation of moisture or impurities through the substrate 110. The buffer layer 111 may be configured by a single layer or a double layer of silicon oxide SiOₓ or silicon nitride SiNₓ but is not limited thereto. However, the buffer layer 111 may be omitted depending on a type of substrate 110 or a type of transistor, but the present disclosure is not limited thereto.

The driving transistor DT, the first transistor T1, and the second transistor T2 are disposed in each of the plurality of sub pixels SP on the buffer layer 111.

The driving transistor DT, the first transistor T1, and the second transistor T2 of each of the plurality of sub pixels SP may be P-type thin film transistors or N-type thin film transistors. For example, since in a P-type thin film transistor, holes move from the source electrode to the drain electrode, the current flows from the source electrode to the drain electrode. Since in an N-type thin film transistor, electrons move from the source electrode to the drain electrode, the current flows from the drain electrode to the source electrode. Hereinafter, the description will be made under the assumption that the driving transistor DT, the first transistor T1, and the second transistor T2 are P-type thin film transistors in which the current flows from the source electrode to the drain electrode, but the present disclosure is not limited thereto.

First, the driving transistor DT is disposed in each of the plurality of sub pixels SP on the buffer layer 111. The driving transistor DT is a transistor which controls a driving current supplied to the light emitting diode 120. In one pixel area UPA, the driving transistor DT of each of the plurality of sub pixels SP may be disposed in one line along the column direction. The plurality of driving transistors DT of the plurality of sub pixels SP may be disposed in one line while overlapping an area in which the reference line RL and the data line DL are disposed.

The driving transistor DT includes a driving active layer DACT, a driving gate electrode DGE, a driving source electrode DSE, and a driving drain electrode DDE.

The driving active layer DACT is disposed on the buffer layer 111. The driving active layer DACT may be formed of a semiconductor material, such as an oxide semiconductor, amorphous silicon, or polysilicon, but is not limited thereto.

A gate insulating layer 112 is disposed on the driving active layer DACT. The gate insulating layer 112 is an insulating layer which insulates the driving active layer DACT from the driving gate electrode DGE. The gate insulating layer 112 may be configured by a single layer or a double layer of silicon oxide SiOₓ or silicon nitride SiNₓ but is not limited thereto.

The driving gate electrode DGE is disposed on the gate insulating layer 112. The driving gate electrode DGE may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

A first interlayer insulating layer 113a is disposed on the driving gate electrode DGE. A contact hole through which the driving source electrode DSE is in contact with the driving active layer DACT is formed in the first interlayer insulating layer 113a. The first interlayer insulating layer 113a is an insulating layer which protects components below the first interlayer insulating layer 113a. The first interlayer insulating layer 113a may be configured by a single layer or a double layer of silicon oxide SiOₓ or silicon nitride SiNₓ but is not limited thereto.

The driving source electrode DSE is disposed on the first interlayer insulating layer 113a. The driving source electrode DSE is electrically connected to the driving active layer DACT through a contact hole formed in the first interlayer insulating layer 113a and the gate insulating layer 112. Further, the driving source electrode DSE may electrically be connected to the second transistor T2. The driving source electrode DSE may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

A second interlayer insulating layer 113b is disposed on the driving source electrode DSE. The second interlayer insulating layer 113b is an insulating layer which protects components below the second interlayer insulating layer 113b. The second interlayer insulating layer 113b may be configured by a single layer or a double layer of silicon oxide SiOₓ or silicon nitride SiNₓ but is not limited thereto.

A first passivation layer 114a is disposed on the second interlayer insulating layer 113b. The first passivation layer 114a is an insulating layer which protects components below the first passivation layer 114a. The first passivation layer 114a may be configured by a single layer or a double layer of silicon oxide SiOₓ or silicon nitride SiNₓ but is not limited thereto.

The driving drain electrode DDE is disposed on the first passivation layer 114a. The driving drain electrode DDE is electrically connected to the driving active layer DACT through a contact hole formed in the first passivation layer 114a, the first interlayer insulating layer 113a, the second interlayer insulating layer 113b, and the gate insulating layer 112. Further, the driving drain electrode DDE may be electrically connected to the low potential power line VSS through a contact hole formed in the first passivation layer 114a. The driving drain electrode DDE may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

Next, the first transistor T1 is disposed in each of the plurality of sub pixels SP on the buffer layer 111. The first transistor T1 is a transistor which transmits a data voltage Vdata to the driving gate electrode DGE of the driving transistor DT and is referred to as a switching transistor. At this time, the plurality of first transistors T1 of the plurality of sub pixels SP are disposed so as to overlap the scan line SL and a protruding part of the scan line SL in one pixel area UPA and may be disposed in one line along the row direction. The row direction may be referred to as a second direction herein.

Specifically, the scan line SL extends in the row direction on the gate insulating layer 112 and may be disposed across the plurality of pixel areas UPA. At this time, the scan line SL may include a part protruding to both sides of the scan line SL toward the plurality of sub pixels SP in an area overlapping the plurality of pixel areas UPA. The part protruding to one side of the scan line SL may include a part extending in a column direction and a part extending to the row direction from an end portion of the part extending in the column direction. That is, the scan line SL may further include a protruding part including a part which protrudes from the scan line SL and at least partially extends in the row direction. For example, a part protruding from one side of the scan line SL may be formed in an L shape. Further, a part protruding from the other side of the scan line SL may include a part extending in the column direction.

Further, the first transistors T1 of the plurality of sub pixels SP at one side of the scan line SL may be disposed in one line along a part of the protruding part of the scan line SL extending in the row direction. Further, the first transistors T1 of the plurality of sub pixels SP at the other side of the scan line SL may be disposed in one line along the scan line SL extending in the row direction. Accordingly, the plurality of first transistors T1 at one side of the scan line SL is disposed in one line along the row direction on the protruding part of the scan line SL and the plurality of first transistors T1 at the other side of the scan line SL may be disposed in one line along the row direction on the scan line SL. The scan line SL is divided into two branches in one pixel area UPA so that the first transistor T1 of the main sub pixel SP and the first transistor T1 of the redundancy sub pixel SP are easily separated. Therefore, the main sub pixel SP and the redundancy sub pixel SP are connected to different first transistors T1 to be driven.

The first transistor T1 includes a first active layer ACT1, a first gate electrode GE1, a first source electrode SE1, and a first drain electrode DE1.

The first active layer ACT1 is disposed between the buffer layer 111 and the gate insulating layer 112. The first active layer ACT1 may be formed of a semiconductor material such as an oxide semiconductor, amorphous silicon, or polysilicon, but is not limited thereto.

The first gate electrode GE1 is disposed on the gate insulating layer 112. The first gate electrode GE1 may be electrically connected to the scan line SL. For example, the first gate electrode GE1 may be integrally formed with the scan line SL. The first gate electrode GE1 may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

The first drain electrode DE1 is disposed between the first interlayer insulating layer 113a and the second interlayer insulating layer 113b. The first drain electrode DE1 is electrically connected to the first active layer ACT1 through a contact hole formed in the first interlayer insulating layer 113a and the gate insulating layer 112. Further, the first drain electrode DE1 may electrically be connected to the second gate electrode GE2 of the second transistor T2 through a contact hole of the first interlayer insulating layer 113a. The first drain electrode DE1 may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

The first source electrode SE1 is disposed on the first passivation layer 114a. The first source electrode SE1 is electrically connected to the first active layer ACT1 through a contact hole formed in the first passivation layer 114a, the second interlayer insulating layer 113b, the first interlayer insulating layer 113a, and the gate insulating layer 112. Further, the first source electrode SE1 may electrically be connected to the data line DL. For example, the first source electrode SE1 may be integrally formed with the data line DL. The first source electrode SE1 may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

Next, the second transistor T2 is disposed in each of the plurality of sub pixels SP on the buffer layer 111. The second transistor T2 is a transistor for compensating for a threshold voltage of the driving transistor DT and is referred to as a sensing transistor. The second transistors T2 of the plurality of sub pixels SP may be disposed in one line along a part of the protruding part of the scan line SL which extends in a column direction. For example, the second transistors T2 of the plurality of sub pixels SP at one side of the scan line SL are disposed so as to correspond to a part of the protruding part of the scan line SL which extends in a column direction. The second transistors T2 of the plurality of sub pixels SP at the other side of the scan line SL may be disposed so as to correspond to the protruding part of the scan line SL. Therefore, the plurality of second transistors T2 disposed in one pixel area UPA may be disposed in one line along the column direction.

The second transistor T2 includes a second active layer ACT2, a second gate electrode GE2, a second source electrode SE2, and a second drain electrode DE2.

The second active layer ACT2 is disposed between the buffer layer 111 and the gate insulating layer 112. The second active layer ACT2 may be formed of a semiconductor material such as an oxide semiconductor, amorphous silicon, or polysilicon, but is not limited thereto.

At this time, the second active layers ACT2 of the plurality of adjacent sub pixels SP may be connected to each other. For example, the second active layers ACT2 of the first sub pixel SP1, the second sub pixel SP2, and the third sub pixel SP3 disposed at one side of the scan line SL are connected to each other while extending in the column direction and are connected to the second drain electrode DE2 disposed in the first sub pixel SP1. Further, the second active layers ACT2 of the first sub pixel SP1, the second sub pixel SP2, and the third sub pixel SP3 disposed at the other side of the scan line SL are connected to each other while extending in the column direction and are connected to the second drain electrode DE2 disposed in the first sub pixel SP1. That is, a connecting part which connects the channel region of the second active layer ACT2 of the plurality of sub pixels SP and the reference line RL is formed of a transparent material of the second active layer ACT2, rather than an opaque conductive material. Therefore, the transmittance at the outermost edge of the pixel area UPA may be improved. Further, the connecting part which connects the channel region of the second active layer ACT2 of the plurality of sub pixels SP and the reference line RL is formed of a material of the second active layer ACT2 so that the contact hole may be omitted and the structure of the pixel area UPA may be simplified.

The second gate electrode GE2 is disposed between the gate insulating layer 112 and the first interlayer insulating layer 113a. The second gate electrode GE2 may be electrically connected to the scan line SL. For example, the second gate electrode GE2 may be integrally formed with the protruding part of the scan line SL to be electrically connected. The second gate electrode GE2 may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

The second source electrode SE2 is disposed between the first interlayer insulating layer 113a and the second interlayer insulating layer 113b. The second source electrode SE2 is electrically connected to the second active layer ACT2 through a contact hole of the first interlayer insulating layer 113a and the gate insulating layer 112. Further, the second source electrode SE2 is integrally formed with the driving source electrode DSE to be electrically connected to the driving source electrode DSE. The second source electrode SE2 may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

The second drain electrode DE2 is disposed between the first passivation layer 114a and a second passivation layer 114b. The second drain electrode DE2 is electrically connected to the second active layer ACT2 through a contact hole formed in the first passivation layer 114a, the second interlayer insulating layer 113b, the first interlayer insulating layer 113a, and the gate insulating layer 112. The second drain electrode DE2 is integrally formed with the reference line RL to be electrically connected to the reference line RL. The second drain electrode DE2 may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

Next, the storage capacitor Cst is disposed on the gate insulating layer 112. The storage capacitor Cst stores a potential difference between the driving gate electrode DGE and the driving source electrode DSE of the driving transistor DT while the light emitting diode 120 emits light, so that a constant driving current may be supplied to the light emitting diode 120. The storage capacitor Cst includes a first capacitor electrode C1 which is electrically connected to the driving gate electrode DGE and a second capacitor electrode C2 which is electrically connected to the driving source electrode DSE. Therefore, the storage capacitor Cst may constantly maintain a voltage of the driving gate electrode DGE and the driving source electrode DSE.

Specifically, the first capacitor electrode C1 is disposed on the gate insulating layer 112. The first capacitor electrode C1 is integrally formed with the driving gate electrode DGE. The second capacitor electrode C2 is disposed on the first interlayer insulating layer 113a. The first capacitor electrode C1 and the second capacitor electrode C2 may be disposed to overlap with the first interlayer insulating layer 113a therebetween. At this time, the second capacitor electrode C2 is integrally formed with the driving source electrode DSE. The first capacitor electrode C1 and the second capacitor electrode C2 may be configured by a single layer or a plurality of layers of a conductive material, such as copper (Cu), aluminum (Al), molybdenum (Mo), nickel (Ni), titanium (Ti), chrome (Cr), or an alloy thereof, but the present disclosure is not limited thereto.

Next, an auxiliary electrode AE is disposed on the first passivation layer 114a. The auxiliary electrode AE is an electrode for electrically connecting the driving source electrode DSE and a first reflective electrode RE1. The driving source electrode DSE and the first reflective electrode RE1 are electrically connected to each other by means of the auxiliary electrode AE. The auxiliary electrode AE may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

A low potential power line VSS is disposed on the second interlayer insulating layer 113b. The low potential power line VSS is disposed along the column direction and overlaps the plurality of pixel areas UPA. The low potential power line VSS may electrically be connected to the driving drain electrode DDE. The low potential power line VSS may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

The reference line RL is disposed on the first passivation layer 114a. In one embodiment, the reference line RL overlaps the driving transistor DT. The reference line RL is disposed along the column direction and overlaps the plurality of pixel areas UPA. The reference line RL is disposed to be adjacent to a protruding part of the scan line SL and may electrically be connected to the plurality of second transistors T2 disposed on the protruding part of the scan line SL. The reference line RL may be configured by a single layer or a plurality of layers of a conductive material, such as copper (Cu), aluminum (Al), molybdenum (Mo), nickel (Ni), titanium (Ti), chrome (Cr), or an alloy thereof, but is not limited thereto.

A plurality of data lines DL are disposed on the first passivation layer 114a. The plurality of data lines DL extend in the column direction and overlap the plurality of pixel areas UPA. The plurality of data lines DL includes a data line DL connected to the first transistors T1 of the plurality of first sub pixels SP1, a data line DL connected to the first transistors T1 of the plurality of second sub pixels SP2, and a data line DL connected to the first transistors T1 of the plurality of third sub pixels SP3. In one embodiment, each data line DL overlaps a corresponding driving transistor DT as shown in FIG. 5.

Next, the second passivation layer 114b is disposed on the driving transistor DT, the first transistor T1, the second transistor T2, the storage capacitor Cst, the reference line RL, and the data line DL. The second passivation layer 114b is an insulating layer which protects components below the second passivation layer 114b and may be configured by a single layer or a double layer of silicon oxide SiOₓ or silicon nitride SiNₓ but is not limited thereto.

The first planarization layer 115a is disposed on the second passivation layer 114b. The first planarization layer 115a may planarize an upper portion of the substrate 110 on which the plurality of transistors and the storage capacitor Cst are disposed. The first planarization layer 115a may be configured by a single layer or a double layer, and for example, may be formed of photoresist or an acryl-based organic material, but is not limited thereto.

In the meantime, even though it is not illustrated in the drawing, an additional passivation layer may be further disposed on the first planarization layer 115a. For example, a passivation layer which is configured by a single layer or a double layer of silicon oxide SiOₓ or silicon nitride SiNₓ may be formed on the first planarization layer 115a to protect configurations below the passivation layer.

Next, a plurality of first reflective electrodes RE1 are disposed on the first planarization layer 115a. The plurality of first reflective electrodes RE1 are disposed in each of the plurality of sub pixels SP to electrically connect the driving transistor DT and the light emitting diode 120 and reflect light emitted from the light emitting diode 120 to the outside of the display device 100. The plurality of first reflective electrodes RE1 may be disposed to be adjacent to the driving source electrode DSE in each of the plurality of sub pixels SP. The plurality of first reflective electrodes RE1 may be formed of an opaque conductive material having a high reflection efficiency, such as titanium (Ti), gold (Au), silver (Ag), copper (Cu), or an alloy thereof, but the present disclosure is not limited thereto.

A second reflective electrode RE2 and the high potential power line VDD are disposed on the first planarization layer 115a. The second reflective electrode RE2 and the high potential power line VDD are integrally formed to reflect light emitted from the light emitting diode 120 to the outside of the display device 100 while supplying a high potential power voltage to the light emitting diode 120. The second reflective electrodes RE2 of the plurality of sub pixels SP are connected to each other to be integrally formed. The second reflective electrode RE2 and the high potential power line VDD extend in the column direction and overlap the light emitting diode 120. The second reflective electrode RE2 and the high potential power line VDD may be disposed so as to overlap the plurality of data lines DL, the reference line RL, and the low potential power line VSS. The second reflective electrode RE2 and the high potential power line VDD may be formed of an opaque conductive material having a high reflection efficiency, such as titanium (Ti), gold (Au), silver (Ag), copper (Cu), or an alloy thereof, but the present disclosure is not limited thereto.

A third passivation layer 114c is disposed on the plurality of first reflective electrodes RE1 and the second reflective electrode RE2. The third passivation layer 114c is an insulating layer which protects components below the third passivation layer 114c and may be configured by a single layer or a double layer of silicon oxide SiOₓ or silicon nitride SiNₓ but is not limited thereto.

An adhesive layer AD is disposed on the third passivation layer 114c. The adhesive layer AD is formed on the front surface of the substrate 110 to fix the light emitting diode 120 disposed on the adhesive layer AD. The adhesive layer AD may be formed of a photo curable adhesive material which is cured by light. For example, the adhesive layer AD may be selected from any one of adhesive polymer, epoxy resist, UV resin, polyimides, acrylates, urethanes, and polydimethylsiloxane (PDMS), but is not limited thereto.

The plurality of light emitting diodes 120 are disposed in each of the plurality of sub pixels SP on the adhesive layer AD. Each light emitting diode 120 is an element which emits light by a current. And each light emitting diode 120 may be a red light emitting diode 120R which emits red light, a green light emitting diode 120G which emits green light, or a blue light emitting diode 120B which emits blue light. Light with various colors including white may be implemented by a combination of the plurality of light emitting diodes 120, e.g. by a combination of a red light emitting diode 120R, a green light emitting diode 120G and a blue light emitting diode 120B. For example, each light emitting diode 120 may be a light emitting diode (LED) or a micro LED, but is not limited thereto.

The red light emitting diode 120R may be disposed in the first sub pixel SP1, the green light emitting diode 120G may be disposed in the second sub pixel SP2, and the blue light emitting diode 120B may be disposed in the third sub pixel SP3. The plurality of light emitting diodes 120 disposed in one pixel area UPA may be disposed in one line along the column direction. Further, the plurality of light emitting diodes 120 may be disposed so as to overlap the second reflective electrode RE2 in each of the plurality of sub pixels SP.

In the meantime, when the plurality of sub pixels SP is divided into the main sub pixel SP and the redundancy sub pixel SP as described above, the plurality of light emitting diodes 120 may also be divided into a main light emitting diode 120 and a redundancy light emitting diode 120. For example, one of one pair of first sub pixels SP1, one of one pair of second sub pixels SP2, and one of one pair of third sub pixels SP3 are main sub pixels SP. Therefore, the red light emitting diode 120R, the green light emitting diode 120G, and the blue light emitting diode 120B disposed in the respective main sub pixel SP may be main light emitting diodes 120. For example, the other one of the one pair of first sub pixels SP1, the other one of the one pair of second sub pixels SP2, and the other one of the one pair of third sub pixels SP3 are redundancy sub pixels SP. Therefore, the red light emitting diode 120R, the green light emitting diode 120G, and the blue light emitting diode 120B disposed in the respective redundancy sub pixel SP may be redundancy light emitting diodes 120.

Each of the plurality of light emitting diodes 120 includes a first semiconductor layer 121, an emission layer 122, a second semiconductor layer 123, a first electrode 124, a second electrode 125, and an encapsulation film 126.

The first semiconductor layer 121 is disposed on the adhesive layer AD and the second semiconductor layer 123 is disposed on the first semiconductor layer 121. The first semiconductor layer 121 and the second semiconductor layer 123 may be layers formed by doping n-type and p-type impurities into a specific material. For example, the first semiconductor layer 121 and the second semiconductor layer 123 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), etc. and the n-type impurity may be silicon (Si), germanium (Ge), tin (Sn), etc., but is not limited thereto.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 may be disposed on the top surface of the first semiconductor layer 121. The first electrode 124 is an electrode which electrically connects the driving transistor DT and the first semiconductor layer 121. In this case, the first semiconductor layer 121 is a semiconductor layer doped with an n-type impurity and the first electrode 124 may be a cathode. The first electrode 124 may be disposed on a top surface of the first semiconductor layer 121 which is exposed from the emission layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 may be disposed on the top surface of the second semiconductor layer 123. The second electrode 125 is an electrode which electrically connects the high potential power line VDD and the second semiconductor layer 123. In this case, the second semiconductor layer 123 is a semiconductor layer doped with a p-type impurity and the second electrode 125 may be an anode. The second electrode 125 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation film 126 is disposed so as to enclose the first semiconductor layer 121, the emission layer 122, the second semiconductor layer 123, the first electrode 124, and the second electrode 125. The encapsulation film 126 is formed of an insulating material to protect the first semiconductor layer 121, the emission layer 122, and the second semiconductor layer 123. In the encapsulation film 126, a contact hole which exposes the first electrode 124 and a contact hole which exposes the second electrode 125 are formed to electrically connect a first connection electrode CE1 and a second connection layer CE2 to the first electrode 124 and the second electrode 125, respectively.

In the meantime, a part of the side surface of the first semiconductor layer 121 may be exposed from the encapsulation film 126 (in other words, the part of the side surface may be not covered by the encapsulation film 126). In the fabrication process of the display device 100, the light emitting diode 120 manufactured on a wafer is separated from the wafer to be transferred onto the display panel PN. However, during the process of separating the light emitting diode 120 from the wafer, a part of the encapsulation film 126 may be torn. For example, a part of the encapsulation film 126 which is adjacent to a lower edge of the first semiconductor layer 121 of the light emitting diode 120 is torn during the process of separating the light emitting diode 120 from the wafer. Accordingly, a part of a lower side surface of the first semiconductor layer 121 may be exposed to the outside. Even though the lower portion of the light emitting diode 120 is exposed from the encapsulation film 126, the first connection electrode CE1 and the second connection electrode CE2 are formed after forming the second planarization layer 115b and the third planarization layer 115c which cover the side surface of the first semiconductor layer 121. Accordingly, a short circuit defect may be reduced or prevented.

Next, the second planarization layer 115b and the third planarization layer 115c are disposed on the adhesive layer AD and the light emitting diode 120.

The second planarization layer 115b overlaps a part of side surfaces of the plurality of light emitting diodes 120 to fix and protect the plurality of light emitting diodes 120. A torn part of the encapsulation film 126 which protects the side surface of the first semiconductor layer 121 of the light emitting diode 120 may be covered by the second planarization layer 115b. By doing this, contacts, and short circuit defects of the connection electrodes and the first semiconductor layer 121 may be suppressed thereafter.

The third planarization layer 115c is formed to cover the second planarization layer 115b and upper portions of the light emitting diode 120. A contact hole which exposes the first electrode 124 and a contact hole which exposes the second electrode 125 of the light emitting diode 120 are formed in the third planarization layer 115c. The first electrode 124 and the second electrode 125 of the light emitting diode 120 are exposed from the third planarization layer 115c (in other words, at least a part of the first electrode 124 and at least a part of the second electrode 125 may not be covered by the third planarization layer 115c), and the third planarization layer 115c is partially disposed in an area between the first electrode 124 and the second electrode 125 to reduce a short circuit defect. The second planarization layer 115b and the third planarization layer 115c may be configured by a single layer or a double layer, and for example, may be formed of photoresist or an acryl-based organic material, but the present disclosure is not limited thereto.

The first connection electrode CE1 and the second connection electrode CE2 are disposed on the third planarization layer 115c.

The first connection electrode CE1 is an electrode which electrically connects the first electrode 124 of the light emitting diode 120 and the driving transistor DT. The first connection electrode CE1 is electrically connected to the first electrode 124 exposed from the third planarization layer 115c and is electrically connected to the first reflective electrode RE1 through a contact hole formed in the third planarization layer 115c, the second planarization layer 115b, the adhesive layer AD, and the third passivation layer 114c, simultaneously. Therefore, the first electrode 124 and the driving source electrode DSE may electrically be connected through the first connection electrode CE1, the first reflective electrode RE1, and the auxiliary electrode AE.

The second connection electrode CE2 is an electrode which electrically connects the second electrode 125 of the light emitting diode 120 and the high potential power line VDD. The second connection electrode CE2 is electrically connected to the second electrode 125 exposed from the third planarization layer 115c. And the second connection electrode CE2 is electrically connected to the second reflective electrode RE2 and the high potential power line VDD through a contact hole formed in the third planarization layer 115c, the second planarization layer 115b, the adhesive layer AD, and the third passivation layer 114c. Accordingly, the second electrode 125 and the high potential power line VDD are electrically connected through the second connection electrode CE2.

The first connection electrode CE1 and the second electrode CE2 may be formed of a transparent conductive material, such as indium tin oxide (ITO) or indium zinc oxide (IZO) but are not limited thereto.

In the meantime, in the drawing, it is illustrated that the driving source electrode DSE of the driving transistor DT and the first electrode 124 of the light emitting diode 120 are electrically connected. However, the driving drain electrode DDE of the driving transistor DT and the second electrode 125 of the light emitting diode 120 may be electrically connected depending on a type of the driving transistor DT and a design of the pixel circuit.

Next, in the pixel area UPA, a bank BB is disposed on the third planarization layer 115c, the first connection electrode CE1, and the second connection electrode CE2. The bank BB may be disposed to be spaced apart from the light emitting diode 120 with a predetermined interval. The bank BB is disposed at a boundary between the plurality of sub pixels SP and covers a part of the first connection electrode CE1 and the second connection electrode CE2. The bank BB may be disposed to be spaced apart from a transmissive area TA. The bank BB may be formed of an opaque material to reduce color mixture between the plurality of sub pixels SP and for example, may be formed of black resin, but is not limited thereto.

A protection layer 116 is disposed on the first connection electrode CE1, the second connection electrode CE2, and the bank BB. The protection layer 116 is a layer for protecting configurations below the protection layer 116. The protection layer 116 may be configured as a single layer or a double layer, for example, may be formed of benzocyclobutene (BCB), translucent epoxy, photoresist, an acryl-based organic material, or an inorganic material such as silicon oxide SiOₓ, or silicon nitride SiNₓ but is not limited thereto.

In the meantime, in order to expand a size of the transmissive area TA, the plurality of sub pixels SP may be disposed so as to overlap the plurality of wiring lines. At this time, driving current fluctuation may occur in each of the plurality of sub pixels SP due to some wiring lines. For example, the driving transistor DT and the storage capacitor Cst of each of the plurality of sub pixels SP overlap the data line DL to be coupled to the data line DL. As shown in FIG. 5, the data line DL overlaps at least one of the driving source electrode DSE, the driving gate electrode DGE, or the driving active layer DACT. In this case, the voltage of the driving gate electrode DGE may fluctuate due to a data line to which a different voltage is applied at every frame. As the voltage of the driving gate electrode DGE fluctuates, a driving current which flows through the light emitting diode 120 fluctuates and a luminance change is caused due to a cross talk to deteriorate a display quality.

Therefore, in the display device 100 according to the exemplary embodiment of the present disclosure, a thickness of an insulating layer is adjusted in consideration of a permittivity of the insulating layer disposed between the storage capacitor Cst and the driving transistor DT and the data line DL. Accordingly, the voltage fluctuation of the driving gate electrode DGE due to the data line DL may be reduced. For example, inorganic insulating layers disposed on the substrate 110, that is, the insulating layers such as the buffer layer 111, the gate insulating layer 112, the first interlayer insulating layer 113a, and the second passivation layer 114b may be formed to have a thickness of several thousand angstroms (Å). However, the thicknesses of the first passivation layer 114a and the second interlayer insulating layer 113b which are insulating layers disposed between the data line DL and the storage capacitor Cst are different from the thicknesses of the other insulating layers to be at least several micrometers (μm). By doing this, the voltage fluctuation of the driving transistor DT due to the data line DL may be minimized. Therefore, a thickness of the insulating layer between the data line DL and the storage capacitor Cst may be larger than a thickness of the buffer layer 111, a thickness of the gate insulating layer 112, a thickness of the first interlayer insulating layer 113a, and a thickness of the second passivation layer 114b.

Referring to FIG. 6, when a width of the data line DL is 1 μm, the thickness of the insulating layer may be determined by a material and a permittivity of the insulating layer disposed below the data line DL. As the thickness of the insulating layer is increased, a luminance change level due to the cross talk may be reduced. At this time, when the insulating layer is formed of silicon nitride SiNₓ having a permittivity of approximately 6.69 and a target cross talk is 2%, the thickness of the insulating layer is formed to be approximately 16.55 μm or larger to control the luminance change level due to the cross talk below 2%. At this time, when the insulating layer is formed of silicon oxide SiOₓ having a permittivity of approximately 4.3 and a target cross talk is 2%, the thickness of the insulating layer is formed to be approximately 10.64 μm or larger to control the luminance change level due to the cross talk below 2%. Therefore, when a width of the data line DL is 1 μm, an overall thickness of the first passivation layer 114a and the second interlayer insulating layer 113b are formed to be at least 10.64 μm or larger to minimize the fluctuation of the voltage of the driving transistor DT and the storage capacitor Cst connected to the driving transistor DT due to the data line DL. Further, as the width of the data line DL is increased, in order to implement the same level of cross talk, a thicker insulating layer may be necessary.

Accordingly, in consideration of the width of the data line DL, permittivity of the first passivation layer 114a and the second interlayer insulating layer 113b, and a target cross talk level, the overall thicknesses of the first passivation layer 114a and the second interlayer insulating layer 113b may be determined. Further, the driving current may be maintained constant while minimizing interference between the data line DL and the driving transistor DT, and the storage capacitor Cst connected to the driving transistor DT.

In the display device 100 according to the exemplary embodiment of the present disclosure, the plurality of pixel areas UPA are disposed in an area in which a plurality of wiring lines extending in a column direction are disposed to maximize a size of the transmissive area TA. The pixel area UPA which includes the pixel circuit and the light emitting diode 120 to be substantially opaque is disposed together with an opaque wiring line to reduce a size of the opaque area in the active area AA. For example, a data line DL and/or or a reference line RL (as an example of an opaque wiring line that extends in the column direction) may be disposed so as to overlap with the light emitting diode 120 in a plan view of the display device 100. For example, the data line DL and/or the reference line RL may be disposed between the light emitting diode 120 and a thin film transistor (e.g., the driving transistor DT) and/or the storage capacitor Cst of the pixel circuit in a cross-sectional view of the display device 100. Therefore, the size of the transmissive area TA is maximized to improve an overall transmittance of the display device 100 and implement a transparent display device 100.

In the display device 100 according to the exemplary embodiment of the present disclosure, voltage fluctuation of the driving transistor DT due to the data line DL may be minimized or at least reduced. When the data line DL and the pixel area UPA are formed to overlap in order to ensure the size of the transmissive area TA, the configuration of the data line DL and the pixel area UPA may be coupled, thereby causing voltage fluctuations. For example, the data line DL which overlaps the driving transistor DT and the storage capacitor Cst thus may be coupled to the driving transistor DT and the storage capacitor Cst, and the voltages of the driving transistor DT and the storage capacitor Cst may fluctuate so that the luminance fluctuates, and the display quality may be deteriorated. Therefore, the insulating layer between the data line DL and the driving transistor DT and the storage capacitor Cst is formed to be thick to minimize or at least reduce the influence of the data line DL. At this time, the thickness of the insulating layer may be determined in consideration of the permittivity of the insulating layer, the width of the data line DL, and a target cross talk level. Accordingly, in the display device 100 according to the exemplary embodiment of the present disclosure, a thickness of an insulating layer between the data line DL and the driving transistor DT, among the plurality of insulating layers, is formed to be relatively thick. Therefore, the fluctuation of the driving current due to the data line DL is minimized or at least reduced and the display quality may be improved.

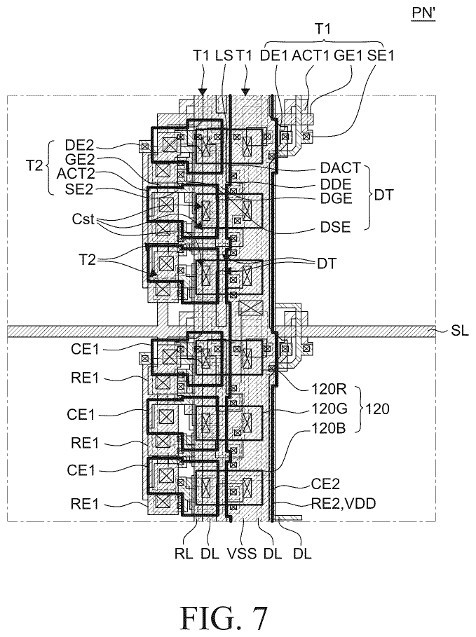

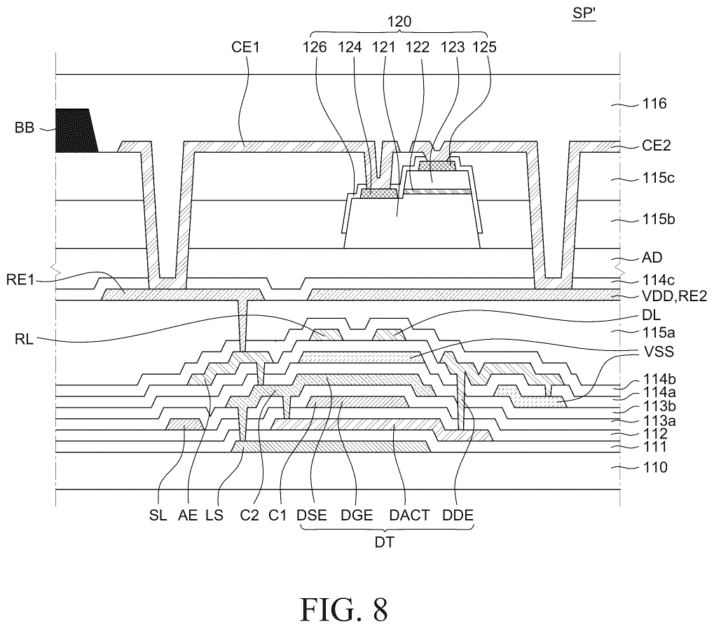

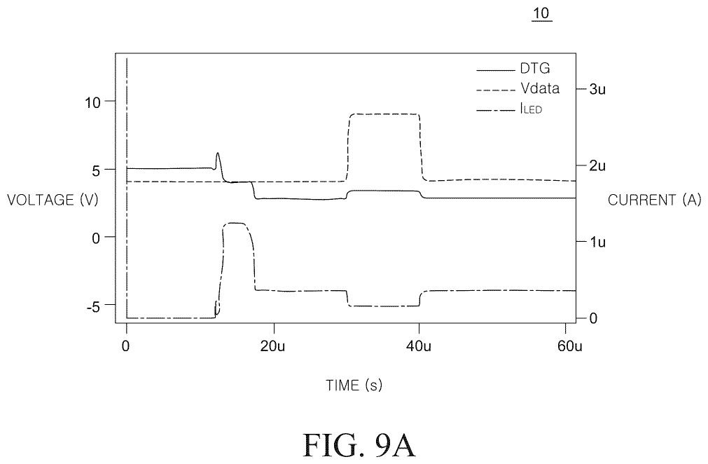

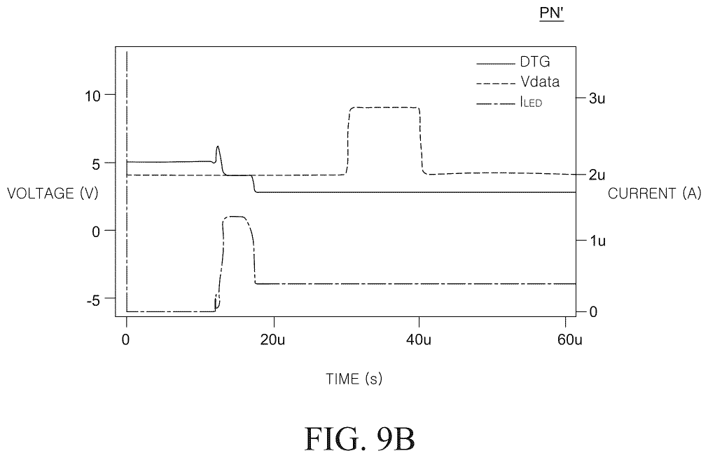

FIG. 7 is an enlarged plan view of a display device according to another exemplary embodiment of the present disclosure. FIG. 8 is a cross-sectional view of a sub pixel of a display device according to another exemplary embodiment of the present disclosure. FIG. 9A is a graph obtained by measuring a voltage and a driving current of a driving gate electrode according to a data voltage in a display device according to a comparative embodiment. FIG. 9B is a graph obtained by measuring a voltage and a driving current of a driving gate electrode according to a data voltage in a display device according to another exemplary embodiment of the present disclosure. In a display panel PN′ of FIGS. 7 and 8, only a low potential power line VSS is different from the display panel PN of FIGS. 1 to 5, but the other configurations are substantially the same so that a redundant description will be omitted.

Referring to FIGS. 7 and 8, the low potential power line VSS is disposed so as to overlap the plurality of data lines DL between the second interlayer insulating layer 113b and the first passivation layer 114a. The low potential power line VSS may overlap an area in which the plurality of data lines DL are disposed. The low potential power line VSS has a relatively large width so that one low potential power line VSS and the plurality of data lines DL overlap. The low potential power line VSS may cover the storage capacitor Cst and the driving transistor DT of the plurality of sub pixels SP′. Only the low potential power line VSS is disposed between the second interlayer insulating layer 113b and the first passivation layer 114a so that the low potential power line VSS may be easily formed in a remaining area excluding an area in which a contact hole is disposed.

In the low potential power line VSS, an opening which overlaps the contact hole may be formed. For example, in the low potential power line VSS, an opening which overlaps a contact hole through which the first source electrode SE1 and the first active layer ACT1 are connected and a contact hole through which the driving drain electrode DDE and the driving active layer DACT are connected may be formed. The first source electrode SE1 and the driving drain electrode DDE are disposed on the low potential power line VSS and the first active layer ACT1 and the driving active layer DACT are disposed below the low potential power line VSS. Therefore, the opening is formed in the low potential power line VSS to easily connect configurations connected to an upper portion and a lower portion of the low potential power line VSS.

The low potential power line VSS is disposed between the storage capacitor Cst and the plurality of data lines DL and between the driving transistor DT and the plurality of data lines DL to serve as a blocking film which blocks the voltage fluctuation of the driving transistor DT due to the data line DL. The low potential power line VSS to which a constant voltage is applied is disposed between the storage capacitor Cst and the driving transistor DT and the data lines DL to suppress the coupling of the data line DL and the storage capacitor Cst and the driving transistor DT. The low potential power line VSS is disposed so as to cover at least the driving gate electrode DGE of the driving transistor DT to protect the voltage DTG of the driving gate electrode DGE from fluctuating due to the data line DL.

Hereinafter, an effect of expanding the low potential power line VSS will be described with reference to FIGS. 9A and 9B.

Referring to FIG. 9A, a display device 10 according to a comparative embodiment has a structure in which a low potential power line VSS is not disposed between the data line DL and the driving transistor DT. In the display panel 10 according to a comparative embodiment, a separate blocking film is not disposed between the data line DL and the driving transistor DT so that it is confirmed that a voltage DTG of the driving gate electrode DGE fluctuates according to the voltage fluctuation of the data line DL. It is also confirmed that as the voltage DTG of the driving gate electrode DGE fluctuates, the driving current ILED which flows through the light emitting diode 120 also fluctuates. In this case, the luminance fluctuates so that the display quality may be deteriorated.

Referring to FIG. 9B, in a display panel PN′ according to another exemplary embodiment of the present disclosure, a low potential power line VSS which serves as a blocking film is disposed between the data line DL and the driving transistor DT and between the data line DL and the storage capacitor Cst. Therefore, even though the voltage of the data line DL fluctuates, the voltage DTG and the driving current ILED of the driving gate electrode DGE may be maintained constant. Accordingly, the luminance is maintained constant, and the display quality may be improved.

In the display panel PN′ according to another exemplary embodiment of the present disclosure, the low potential power line VSS is formed between the data line DL and the driving transistor DT to minimize the voltage fluctuation of the driving transistor DT due to the data line DL. The low potential power line VSS may be disposed to cover the driving transistor DT and the storage capacitor Cst below the plurality of data lines DL. The low potential power line VSS which always maintains a constant voltage may block the plurality of data lines DL from interfering with the driving transistor DT and the storage capacitor Cst. In this case, the voltage DTG and the driving current ILED of the driving gate electrode DGE may be maintained constant without forming the insulating layer between the plurality of data lines DL, and the driving transistor DT, and the storage capacitor Cst to be thick. Further, instead of forming a separate blocking film, a size of the existing low potential power line VSS is expanded so as to correspond to an area in which the plurality of data lines DL are disposed so that the low potential power line VSS is used as a blocking film. Further, the manufacturing process of the display panel PN′ may be simplified. Accordingly, in the display panel PN′ according to another exemplary embodiment of the present disclosure, the low potential power line VSS is formed with an increased size so as to overlap all of the plurality of data lines DL. Therefore, the driving current ILED of the sub pixel SP′ is stably maintained constant and the reliability of the display panel PN′ is improved.

In the meantime, in the related art, the main light emitting diode and the redundancy light emitting diode are disposed together in one sub pixel and the main light emitting diode and the redundancy light emitting diode are connected in parallel in one pixel circuit. In this case, the first electrode and the second electrode of the main light emitting diode and the first electrode and the second electrode of the redundancy light emitting diode are connected to the same node, that is, the same electrode. When a short circuit defect of the light emitting diode or the pixel circuit occurs in this structure, both the main light emitting diode and the redundancy light emitting diode which are connected in parallel and share a specific electrode are darkened to cause a defect. Further, it is difficult to separate and repair only a defective light emitting diode.

In contrast, in the display panels PN and PN′ according to various exemplary embodiments of the present disclosure, as described above, the plurality of sub pixels SP and SP′ are divided into main sub pixels SP and SP′ including the main light emitting diode 120 and redundancy sub pixels SP and SP′ including the redundancy light emitting diode 120. Further, the main light emitting diode 120 of the main sub pixels SP and SP′ and the redundancy light emitting diode 120 of the redundancy sub pixels SP and SP′ may be independently driven. That is, a pixel circuit for driving the main light emitting diode 120 and a pixel circuit for driving the redundancy light emitting diode 120 may be separately formed. For example, in the scan line SL extending in the row direction, an L-shaped protruding part is further formed. One of a first transistor T1 for driving the main light emitting diode 120 and a first transistor T1 for driving the redundancy light emitting diode 120 is formed on the scan line SL and the other one is formed on the L-shaped protruding part. Therefore, the first transistor T1 for driving the main light emitting diode 120 and the first transistor T1 for driving the redundancy light emitting diode 120 may be separately formed. Accordingly, a protruding part is further formed in the scan line SL to individually form the first transistor T1 for the main light emitting diode 120 and the first transistor T1 for the redundancy light emitting diode 120 and individually drive the main light emitting diode 120 and the redundancy light emitting diode 120. Therefore, in the display panels PN and PN′ according to various exemplary embodiments of the present disclosure, the main light emitting diode 120 and the redundancy light emitting diode 120 are connected to different pixel circuits. Accordingly, a defect of a specific sub pixel SP or SP′ does not affect another sub pixel SP or SP′ and only the defective sub pixel SP or SP′ may be easily detected and repaired.

Exemplary embodiments of the present disclosure can also be described as follows:

According to an aspect of the present disclosure, a display device includes a substrate in which a plurality of pixel areas disposed to be spaced apart from each other and a plurality of transmissive areas disposed between the plurality of pixel areas are defined, and a plurality of data lines which extend in a column direction on the substrate. The plurality of pixel areas overlap an area in which the plurality of data lines are disposed.

The display device may further include a plurality of sub pixels disposed in each of the plurality of pixel areas. The plurality of sub pixels may include a first sub pixel having a rectangular shape, a second sub pixel which encloses two adjacent sides among four sides of the first sub pixel, and a third sub pixel which encloses an outside part of the second sub pixel, and the first sub pixel, the second sub pixel, and the third sub pixel may form one rectangular shape.

The display device may further include a scan line which extends in a row direction across the plurality of pixel areas on the substrate. The plurality of sub pixels of each of the plurality of pixel areas may be formed by one first sub pixel, one second sub pixel, and one third sub pixel disposed at one side of the scan line and one first sub pixel, one second sub pixel, and one third sub pixel disposed at the other side (e.g., opposite side) of the scan line.

Each of the plurality of sub pixels may further include a first transistor which is disposed between the plurality of data lines and the substrate and is electrically connected to the plurality of data lines, a driving transistor which is disposed between the plurality of data lines and the substrate and is electrically connected to the first transistor, a second transistor which is disposed between the plurality of data lines and the substrate and is electrically connected to the driving transistor, a storage capacitor which is disposed between the plurality of data lines and the substrate and is electrically connected to a gate electrode of the driving transistor, and a light emitting diode which is disposed on the plurality of data lines and is electrically connected to the driving transistor.

In one pixel area among the plurality of pixel areas, the first transistors of the first sub pixel, the second sub pixel, and the third sub pixel may be disposed in one line along a row direction.

In one pixel area among the plurality of pixel areas, the scan line may include a protruding part which protrudes from the scan line and at least partially extends in the row direction, the first transistors of one first sub pixel, one second sub pixel, and one third sub pixel disposed at one side of the scan line may be disposed on the protruding part of the scan line, and the first transistors of one first sub pixel, one second sub pixel, and one third sub pixel disposed at the other side of the scan line may be disposed on the scan line.

In one pixel area among the plurality of pixel areas, the second transistors of the first sub pixel, the second sub pixel, and the third sub pixel may be disposed in one line along a column direction.

In one pixel area among the plurality of pixel areas, the driving transistors of the first sub pixel, the second sub pixel, and the third sub pixel may be disposed in one line along a column direction.

In one pixel area among the plurality of pixel areas, the light emitting diodes of the first sub pixel, the second sub pixel, and the third sub pixel may be disposed in one line along a column direction.

The plurality of data lines may be disposed on the driving transistor and the storage capacitor and may overlap the driving transistor and the storage capacitor.

The display device may further include a buffer layer disposed between the substrate and the driving transistor, a gate insulating layer disposed between a driving gate electrode and a driving active layer of the driving transistor on the buffer layer, a first interlayer insulating layer which covers the driving transistor, and the one or more insulating layers which cover the storage capacitor on the first interlayer insulating layer. The plurality of data lines may be disposed on one or more insulating layers and a thickness of the one or more insulating layers may be larger than a thickness of the buffer layer, a thickness of the gate insulating layer, and a thickness of the first interlayer insulating layer.

The display device may further include a low potential power line which is disposed between the storage capacitor and the plurality of data lines. The low potential power lines may overlap an area in which the plurality of data lines are disposed.

The low potential power line may overlap the driving transistor and the storage capacitor.

A driving active layer of the driving transistor and a first active layer of the first transistor may be disposed below the low potential power line, a driving drain electrode of the driving transistor and a first source electrode of the first transistor may be disposed on the low potential power line, and the low potential power line may include a plurality of openings which overlaps a contact hole through which the driving active layer and the driving drain electrode are connected and a contact hole through which the first active layer and the first source electrode are connected.

According to another aspect of the present disclosure, a display device may include: a substrate including a plurality of pixel areas that are spaced apart from each other and a plurality of transmissive areas between the plurality of pixel areas, wherein each of the plurality of pixel areas includes a plurality of sub pixels; and a plurality of signal lines that extend in a first direction on the substrate, wherein the plurality of sub pixels include a plurality of pixel circuits, wherein the plurality of signal lines overlap the plurality of pixel circuits without the plurality of signal lines overlapping the plurality of transmissive areas.

Each sub pixel may include a light emitting diode, and each signal line of the plurality of signal lines may be disposed such that it overlaps with at least one of the light emitting diodes in a plan view of the display device.

Each pixel circuit may include a thin film transistor and a storage capacitor, wherein each signal line of the plurality of signal lines may be disposed between at least one of the light emitting diodes and at least one of the thin film transistors and/or storage capacitors in a cross-sectional view of the display device.

The plurality of transmissive areas may be disposed directly adjacent to the plurality of pixel areas.

The display device may further include: a scan line that extends in a second direction across the plurality of pixel areas on the substrate, the second direction different from the first direction, wherein the plurality of sub pixels of each of the plurality of pixel areas may include a first main sub pixel, a second main sub pixel, and a third main sub pixel at a first side of the scan line and a first redundancy sub pixel, a second redundancy sub pixel, and a third redundancy sub pixel at a second side of the scan line, wherein the first main sub pixel and the first redundancy sub pixel emit a first color of light, the second main sub pixel and the second redundancy sub pixel emit a second color of light, and the third main sub pixel and the third redundancy sub pixel emit a third color of light.

The plurality of signal lines may include at least one of a plurality of data lines and a plurality of reference lines.

Each of the plurality of sub pixels may further include: a first transistor between a data line from the plurality of data lines and the substrate, the first transistor electrically connected to the data line; a driving transistor between the data line and the substrate, the driving transistor electrically connected to the first transistor; a second transistor between the data line and the substrate, the second transistor electrically connected to the driving transistor; a storage capacitor between the data line and the substrate, the storage capacitor electrically connected to a gate electrode of the driving transistor; and a light emitting diode over the data line, the light emitting diode electrically connected to the driving transistor.

In one pixel area among the plurality of pixel areas, the first transistor of the first sub pixel, the first transistor of the second sub pixel, and the first transistor of the third sub pixel may be disposed in one line along a second direction that is different from the first direction.

In the one pixel area, a scan line may include a protruding part that protrudes from the scan line in the first direction and at least partially extends in the second direction, the first transistor of a first main sub pixel, the first transistor of a second main sub pixel, and the first transistor of a third main sub pixel at a first side of the scan line may be on the protruding part of the scan line, and the first transistor of a first redundancy sub pixel, the first transistor of a second redundancy sub pixel, and the first transistor of a third redundancy sub pixel at a second side of the scan line may be on the scan line, wherein the first main sub pixel and the first redundancy sub pixel may emit a first color of light, the second main sub pixel and the second redundancy sub pixel may emit a second color of light, and the third main sub pixel and the third redundancy sub pixel may emit a third color of light.

In one pixel area among the plurality of pixel areas, the second transistor of the first sub pixel, the second transistor of the second sub pixel, and the second transistor of the third sub pixel may be disposed in one line along the first direction.

In one pixel area among the plurality of pixel areas, the driving transistor of the first sub pixel, the driving transistor of the second sub pixel, and the driving transistor of the third sub pixel may be disposed in one line along the first direction.

In one pixel area among the plurality of pixel areas, the light emitting diode of the first sub pixel, the light emitting diode of the second sub pixel, and the light emitting diode of the third sub pixel may be disposed in one line along the first direction.

The plurality of signal lines may be over the driving transistor and the storage capacitor and overlap the driving transistor and the storage capacitor.

The display device may further include: a buffer layer between the substrate and the driving transistor; a gate insulating layer on the buffer layer, the gate insulating layer between a driving gate electrode and a driving active layer of the driving transistor; a first interlayer insulating layer that covers the driving transistor; and one or more insulating layers that cover the storage capacitor on the first interlayer insulating layer, wherein the plurality of signal lines may be on the one or more insulating layers and a thickness of the one or more insulating layers may be larger than a thickness of the buffer layer, a thickness of the gate insulating layer, and a thickness of the first interlayer insulating layer.

The display device may further include: a power line between the storage capacitor and the plurality of signal lines, the power line overlapping the plurality of signal lines.

The power line may include or may be a low potential power line or a high potential power line.

The power line may overlap the driving transistor and the storage capacitor.

A driving active layer of the driving transistor and a first active layer of the first transistor may be below the power line, a driving drain electrode of the driving transistor and a first source electrode of the first transistor may be on the power line, and the power line may include a plurality of openings that overlap a contact hole through which the driving active layer and the driving drain electrode are connected and a contact hole through which the first active layer and the first source electrode are connected.

The display device may include a reference line, wherein the reference line extends in the first direction on the substrate and overlaps the plurality of pixel areas.

The reference line may not overlap the plurality of transmissive areas.

The reference line may overlap with at least one of the light emitting diodes in a plan view of the display device.

The reference line may be disposed between at least one of the light emitting diodes and at least one of the driving transistors and/or storage capacitors in a cross-sectional view of the display device.

The reference lines may be electrically connected to the second transistor, and the reference lines may be disposed in the same level as that of the data lines.

The reference lines may be integrally formed with a second drain electrode of the second transistor.

The plurality of sub pixels may include: a first sub pixel having a rectangular shape in a plan view of the display device; a second sub pixel that encloses two adjacent sides among four sides of the first sub pixel in the plan view; and a third sub pixel that encloses an outside part of the second sub pixel in the plan view, wherein the first sub pixel, the second sub pixel, and the third sub pixel collectively form a rectangular shape.

According to another aspect of the present disclosure, a display device may include: a substrate including a pixel area and a light transmitting area that is more transparent than the pixel area; a driving transistor in the pixel area; a power line over the driving transistor in the pixel area; a signal line over the power line in the pixel area; a light emitting element in the pixel area, the light emitting element electrically connected to the driving transistor.

The driving transistor may include a gate electrode, a source electrode, a drain electrode, and an active layer, the signal line overlapping at least one of the source electrode, the gate electrode, or the active layer.

In a cross-sectional view, the signal line may be between the driving transistor and the power line and overlap the driving transistor the power line.

The signal line may be a data line that is configured to supply a data voltage.

The display device may include a first insulating layer on the substrate.

The display device may include a second insulating layer between the signal line and the driving transistor.

The first insulating layer may be between the substrate and the driving transistor, or between different layers of the driving transistor, or between the driving transistor and the second insulating layer.

The second insulating layer may have a thickness that is greater than a thickness of the first insulating layer.

The first insulating layer may include at least one of a buffer layer between the substrate and the driving transistor, a gate insulating layer between the gate electrode and the active layer of the driving transistor, or a first interlayer insulating layer that covers the driving transistor.

The power line may be a low potential power line overlapping the signal line and the driving transistor.

The display device may further include: a scan line in the pixel area, the scan line including a first part that protrudes from the scan line in a first direction and a second part that at least partially extends in a second direction that is different from the first direction in the pixel area.

The pixel area may include a plurality of main sub pixels at a first side of the second part of the scan line and a plurality of redundancy sub pixels at a second side of the second part of the scan line.

The plurality of main sub pixels may include a first main sub pixel that is configured to emit light of a first color, a second main sub pixel that is configured to emit light of a second color, and a third main sub pixel that is configured to emit light of a third color, and the plurality of redundancy sub pixels may include a first redundancy sub pixel that is configured to emit light of the first color, a second redundancy sub pixel that is configured to emit light of the second color, and a third redundancy sub pixel that is configured to emit light of the third color, wherein each of the plurality of main sub pixels and each of the plurality of redundancy sub pixels may include a corresponding pixel driving circuit.

According to another aspect of the present disclosure, a display device may include: a substrate in which a plurality of pixel areas disposed to be spaced apart from each other and a plurality of transmissive areas disposed between the plurality of pixel areas are defined; and a plurality of wiring lines extending in a column direction on the substrate, wherein the plurality of pixel areas overlaps an area in which the plurality of wiring lines are disposed.

The wiring lines may include one or more of a data line, a reference line, a low potential power line and a high potential power line.

In a plan view of the display device, at least one the plurality of wiring lines may overlap with a light emitting diode and/or a thin film transistor of a pixel circuit disposed in the pixel areas.

In a cross-sectional view of the display device, at least one of the plurality of wiring lines may be disposed between a light emitting diode and a thin film transistor of a pixel circuit disposed in the pixel areas.

Although exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

1. A display device, comprising:
a substrate including a plurality of pixel areas that are spaced apart from each other and a plurality of transmissive areas between the plurality of pixel areas, wherein each of the plurality of pixel areas includes a plurality of sub pixels; and
a plurality of signal lines that extend in a first direction on the substrate,
wherein the plurality of sub pixels include a plurality of pixel circuits, wherein the plurality of signal lines overlap the plurality of pixel circuits without the plurality of signal lines overlapping the plurality of transmissive areas.

2. The display device according to claim 1, further comprising:
a scan line that extends in a second direction across the plurality of pixel areas on the substrate, the second direction different from the first direction,
wherein the plurality of sub pixels of each of the plurality of pixel areas include a first main sub pixel, a second main sub pixel, and a third main sub pixel at a first side of the scan line and a first redundancy sub pixel, a second redundancy sub pixel, and a third redundancy sub pixel at a second side of the scan line,
wherein the first main sub pixel and the first redundancy sub pixel emit a first color of light, the second main sub pixel and the second redundancy sub pixel emit a second color of light, and the third main sub pixel and the third redundancy sub pixel emit a third color of light.

3. The display device according to claim 1, wherein the plurality of signal lines includes at least one of a plurality of data lines and a plurality of reference lines.

4. The display device according to claim 3, wherein each of the plurality of sub pixels further includes:
a first transistor between a data line from the plurality of data lines and the substrate, the first transistor electrically connected to the data line;
a driving transistor between the data line and the substrate, the driving transistor electrically connected to the first transistor;
a second transistor between the data line and the substrate, the second transistor electrically connected to the driving transistor;
a storage capacitor between the data line and the substrate, the storage capacitor electrically connected to a gate electrode of the driving transistor; and
a light emitting diode over the data line, the light emitting diode electrically connected to the driving transistor.

5. The display device according to claim 4, wherein in one pixel area among the plurality of pixel areas, the first transistor of the first sub pixel, the first transistor of the second sub pixel, and the first transistor of the third sub pixel are disposed in one line along a second direction that is different from the first direction.

6. The display device according to claim 5, wherein in the one pixel area, a scan line includes a protruding part that protrudes from the scan line in the first direction and at least partially extends in the second direction, the first transistor of a first main sub pixel, the first transistor of a second main sub pixel, and the first transistor of a third main sub pixel at a first side of the scan line are on the protruding part of the scan line, and the first transistor of a first redundancy sub pixel, the first transistor of a second redundancy sub pixel, and the first transistor of a third redundancy sub pixel at a second side of the scan line are on the scan line,
wherein the first main sub pixel and the first redundancy sub pixel are configured to emit a first color of light, the second main sub pixel and the second redundancy sub pixel are configured to emit a second color of light, and the third main sub pixel and the third redundancy sub pixel are configured to emit a third color of light.

7. The display device according to claim 4, wherein in one pixel area among the plurality of pixel areas, the second transistor of the first sub pixel, the second transistor of the second sub pixel, and the second transistor of the third sub pixel are disposed in one line along the first direction.

8. The display device according to claim 4, wherein in one pixel area among the plurality of pixel areas, the driving transistor of the first sub pixel, the driving transistor of the second sub pixel, and the driving transistor of the third sub pixel are disposed in one line along the first direction.

9. The display device according to claim 4, wherein in one pixel area among the plurality of pixel areas, the light emitting diode of the first sub pixel, the light emitting diode of the second sub pixel, and the light emitting diode of the third sub pixel are disposed in one line along the first direction.

10. The display device according to claim 4, wherein the plurality of signal lines are over the driving transistor and the storage capacitor and overlap the driving transistor and the storage capacitor.

11. The display device according to claim 4, further comprising:
a buffer layer between the substrate and the driving transistor;
a gate insulating layer on the buffer layer, the gate insulating layer between a driving gate electrode and a driving active layer of the driving transistor;
a first interlayer insulating layer that covers the driving transistor; and
one or more insulating layers that cover the storage capacitor on the first interlayer insulating layer,
wherein the plurality of signal lines are on the one or more insulating layers and a thickness of the one or more insulating layers is larger than a thickness of the buffer layer, a thickness of the gate insulating layer, and a thickness of the first interlayer insulating layer.

12. The display device according to claim 4, further comprising:
a power line between the storage capacitor and the plurality of signal lines, the power line overlapping the plurality of signal lines.

13. The display device according to claim 12, wherein the power line includes a low potential power line or a high potential power line.

14. The display device according to claim 12, wherein the power line overlaps the driving transistor and the storage capacitor.

15. The display device according to claim 13, wherein a driving active layer of the driving transistor and a first active layer of the first transistor are below the power line, a driving drain electrode of the driving transistor and a first source electrode of the first transistor are on the power line, and the power line includes a plurality of openings that overlap a contact hole through which the driving active layer and the driving drain electrode are connected and a contact hole through which the first active layer and the first source electrode are connected.

16. The display device according to claim 4, wherein the reference lines are electrically connected to the second transistor, and the reference lines are disposed in the same level as that of the data lines.

17. The display device according to claim 16, wherein the reference lines are integrally formed with a second drain electrode of the second transistor.

18. The display device according to any of claim 1, wherein the plurality of sub pixels comprise:
a first sub pixel having a rectangular shape in a plan view of the display device;
a second sub pixel that encloses two adjacent sides among four sides of the first sub pixel in the plan view; and
a third sub pixel that encloses an outside part of the second sub pixel in the plan view, and
wherein the first sub pixel, the second sub pixel, and the third sub pixel collectively form a rectangular shape.

19. A display device comprising:
a substrate including a pixel area and a light transmitting area that is more transparent than the pixel area;
a driving transistor in the pixel area;
a power line over the driving transistor in the pixel area;
a signal line over the power line in the pixel area;
a light emitting element in the pixel area, the light emitting element electrically connected to the driving transistor.

20. The display device, wherein, in a cross-sectional view, the signal line is between the driving transistor and the power line and overlaps the driving transistor the power line.
